(19) United States
(12) Patent Application Publication
(10) Pub. No.: US 2017/0040559 A1
(43) Pub. Date: Feb. 9, 2017

(54) METHOD FOR CONNECTING A FLEXIBLE ELECTRONIC DEVICE TO AN ELECTRICAL WIRE

(71) Applicant: ARMOR, Nantes (FR)

(72) Inventors: Nicholas Charrier, Nantes (FR); Guillaume Riviere, Reze (FR)

(21) Appl. No.: 15/229,929

(22) Filed: Aug. 5, 2016

(30) Foreign Application Priority Data
Aug. 6, 2015 (FR) 1557590

(51) Int. Cl. H01L 51/44

(52) U.S. Cl. CPC H01L 51/441; H01L 51/448

(57) ABSTRACT

A method is for connecting a flexible organic electronic device to an electrical wire, the method includes: providing a flexible electronic device, providing an electrical wire, providing a contact including at least one conductor comprising a contact face, the contact face defining a contact surface, incision of the encapsulating barrier film defining an incision surface, the incision surface having a maximum dimension and a minimum dimension, the maximum dimension of the incision surface being smaller than the maximum dimension of the contact surface, and assembling the conductor and the conductive strip through the incision to ensure an electronic conduction between the conductor and the electrode.

This patent application claims the benefit of document FR 15 57590 filed on Aug. 6,2015 which is hereby incorporated by reference.

### FIELD OF THE INVENTION

The present invention relates to a method for connecting a flexible organic electronic device to an electrical wire. The present invention also relates to such a flexible organic electronic device.

### BACKGROUND OF THE INVENTION

Flexible organic devices have stacks of the conductor/thin organic layer/conductor type, traditionally used in electronic devices. Such devices are for example current rectifier diodes, solar cells, photodetector cells, capacitances, laser diodes, sensor-type devices, memories, or light-emitting diodes. These in particular involve devices in organic electronics on a flexible plastic substrate.

The invention more particularly applies to the organic photovoltaics (OPV) field. A photovoltaic device is a device able to convert received solar energy into electrical energy. The issue of the performance of the device is a recurring problem. It is therefore desirable to increase the performance of such a device as much as possible, i.e., the ratio between the electrical power produced by the device and the solar energy captured by the device.

An organic photovoltaic device includes at least one organic photovoltaic cell. An organic photovoltaic module is an assembly comprising at least two photovoltaic cells.

Each cell is obtained by depositing several layers, at least the active layer of which is made up of organic molecules. As a result, the photovoltaic effect is obtained using properties of organic semiconductor materials.

The semiconductor materials are organically soluble in organic solvents and make it possible to deposit layers using a coating or printing technique on flexible substrates. These manufacturing methods are compatible with the large-scale production done using continuous methods, such as the roll-to-roll methods (denoted R2R in the rest of the description).

Furthermore, the organic photovoltaic modules have a relatively small thickness. A relatively small thickness refers to a thickness of less than or equal to 500 microns. This allows the modules to have a very thin energy generator.

The lightness, mechanical flexibility and semi-transparency of the organic photovoltaic modules open up possibilities for integration of photovoltaic technology into unprecedented fields for mobile applications or applications including curved surfaces (automobiles, portable electronics, tents, etc.).

However, considering deploying this new generation of photovoltaic module on new markets involves being able to guarantee certain characteristics of the module, in particular the light-to-electricity conversion performance and the lifetime of the devices.

An organic photovoltaic device is in particular illustrated by FIG. 1. In this figure, five layers are superimposed, called:
layer 1, representing a first electrode made up of a conductive material;
layer 3, representing an active layer made up of at least one material of a semiconductive nature, advantageously made up of a mixture of an electron donor material (called type n material) and an electron acceptor material (called type p material). Such semiconductive materials can be a molecule, an oligomer or a conjugated organic polymer. Thus, the active layer can be a heterojunction of an electron donor material and an electron acceptor material assuming the form of a layer or a stack of several layers. It may also be a mixture, on a nanometric scale, of two materials in volume heterojunction form, i.e., a close mixture of two materials on a nanometric scale;
layer 2 and layer 4 representing interface layers made up of materials having the right type of transport (n or p) to perform their electron transport (or injection) role or holes, and
layer 5, a second electrode made up of a metal layer.

The five layers rest on a flexible plastic substrate, for example of the PET type (polyethylene terephthalate) or PEN (polyethylene naphthalate) type.

The materials used in the OPV cells, such as the conjugated polymers, are known for being unstable in the ambient air, and particularly sensitive to the degradation caused by oxygen and humidity (see in particular the article by Morgado, J., R. H. Friend, and F. Cacialli. “Environmental aging of poly (p-phenylenevinylene) based light-emitting diodes.” Syntheticmetals 114.2 (2000): 189-196 and the article by Sutherland, D. G. J., et al. “Photo-oxidation of electroluminescent polymers studied by core-level photoabsorption spectroscopy.” Applied physics letters 68.15 (1996): 2046-2048).

The conjugated skeleton of the photoactive semiconductive polymers, combined with the introduction of side chains allowing the solubilization of these products, is very unstable. This unstable nature is in particular shown in the article by Manceau M et al, “Photochemical stability of 7-conjugated polymers for polymer solar cells: a rule of thumb”. J. Mater. Chem., (2011), 21, 4132.

In the article by Norrman, Kion, et al. “Degradation patterns in water and oxygen of an inverted polymer solar cell.” Journal of the American Chemical Society 132.47 (2010): 16883-16892, it was proven that under light radiation, semiconductive polymers become degraded. In a first step, the side chains are oxidized, initiating a chain reaction that leads to the degradation of the very structure of the polymer. This modifies the optical and conductive properties of the photosensitive materials and affects the performance of the devices.

In the article by Tournebize A. et al. “Is there a photostable conjugated polymer for efficient solar cells?” Polymer Degradation and Stability 112 (2015): 175-184, it is also described the water can affect the interface between the metal electrodes and the organic semiconductive layers through an electrochemical process causing the delamination of the electrode.

These degradation phenomena of OPV devices can be caused by intrinsic sources (stability of the materials, chemical interaction at the interfaces, solvent residues, delamination, etc.) or extrinsic ones (diffusion of oxygen or moisture through the encapsulation, problem of filtration of ultraviolet (UV) rays, crushing of the layers, chemical interaction with the glue, etc.). This is in particular described in the article by Grossiord, Nadia, et al. “Degradation mechanisms in organic photovoltaic devices.” Organic Electronics 13.3 (2012): 432-456.

It is crucial to ensure the extrinsic stability of the OPV modules directly related to the quality of the encapsulation, as well as the usage conditions. The choice of materials (barrier film, adhesives, connector technologies) and the encapsulation design are decisive for the performance of the modules over time. The aging issues specific to organic photovoltaics therefore require an encapsulation of the modules immediately after coating. The organic photovoltaic devices are encapsulated between ultra-barrier materials or films protecting them from the intrusion of oxygen and humidity.

The available barrier films are generally made from a stack of polyester films and metal oxide layers (generally alumina oxide) providing the insulation and protection from intrusions by oxygen and moisture. These barrier films are in particular characterized by the permeability parameters of the film with respect to water (typically denoted WVTR for Water Vapor Transmission Rate) and permeability to oxygen (typically denoted OTR for Oxygen Transmission Rate). The adhesion between the barrier films and the photovoltaic device is provided by an adhesive of the pressure-sensitive adhesive (PSA) type, UV thermosetting adhesives, or thermoplastic films.

The electrical current generated by an OPV module passes directly toward metal conductive strips or current collectors (up to 0.2 mm thick and 10 mm wide) that are deposited on thin coated metal electrodes of the peripheral cells of the module. The module and these current collectors are included in the encapsulation in order to seal the module.

The necessary sealing of the device does not make it possible to manufacture modules whereof the current collectors are accessible outside the module, as is the case in the manufacture of photovoltaic modules made from silicon or thin layers. The current collectors are therefore placed on the electrodes and encapsulated and sealed to form the final device. As a result, it is desirable to have a method making it possible to regain contact at the current collectors to power an application or a battery.

The connection devices of the existing photovoltaic modules, called junction housings, provide the electrical connection between the current collectors of the photovoltaic module and an outside electrical wire. Traditionally, the connection established by the housing and the current collector is done by a tab. U.S. Pat. No. 7,705,234 B2 describes a junction housing positioned on a solar module and including a metal tab applied dynamically directly on an electrode exposed to the air of the solar module and connecting the module to an electric cable.

These openings in order to create a contact resumption zone create exposure zones to oxygen and humidity, accelerating the aging of the module and canceling out the effects of the measures taken to hermetically encapsulate the OPV module.

### SUMMARY OF THE INVENTION

There is therefore a need for a method making it possible to obtain a flexible electric device, in particular an electrically connected organic photovoltaic device, having a better performance and a longer lifetime.

To that end, the present description in particular pertains to a method for connecting a flexible organic electronic device to an electrical wire, the method including a step for providing a flexible electronic device. The device comprises a flexible module comprising an electrode, a conductive strip deposited on the electrode, and an encapsulating barrier film encapsulating the module, providing an electrical wire. The method comprises steps for providing a contact member including at least one conductive element comprising a contact face, the contact face defining a contact surface, the contact surface having a maximum dimension and a minimum dimension, incision of the encapsulating barrier film defining an incision surface, the incision surface having a maximum dimension and a minimum dimension, the maximum dimension of the incision surface being strictly smaller than the maximum dimension of the contact surface, and assembling the conductive element and the conductive strip through the incision to ensure an electronic conduction between the conductive element and the electrode.

The present invention relates to a new method for connecting a flexible organic device to wired connector technology. This method seeks to improve the state of the art by:
minimizing the exposure of the organic materials making up the devices to the intrusion of air and moisture;
contributing to the stability of the light energy conversion performance;
improving the lifetime of the devices;
having light and compact connector technology preserving the characteristics of lightness and mechanical flexibility of the devices.

According to specific embodiments, the method comprises one or more of the following features, considered alone or according to any technically possible combinations:
the method includes a step for coating at least part of the contact face of a metal element solidifying under heat to perform welding, the assembly step is implemented by using the contact face.
the ratio between the maximum dimension of the incision surface and the minimum dimension of the contact surface is comprised between 0.9 and 1.2.
the ratio between the maximum dimension of the incision surface and the minimum dimension of the contact surface is strictly less than 1.0.
the ratio between the minimum dimension of the incision surface and the minimum dimension of the contact surface is strictly less than 1.0.
the ratio between the minimum dimension of the incision surface and the maximum dimension of the contact surface is strictly less than 0.25.
the conductive element includes an insertion blade supporting the contact face, the insertion blade having a thickness, the ratio between the minimum dimension of the incision surface and the thickness of the insertion blade is comprised between 0.9 and 1.2.
the ratio between the minimum dimension of the incision surface and the thickness of the insertion blade is strictly less than 1.0.
the conductive element includes an insertion blade supporting the contact face and a support blade, the angle between the support blade and the insertion blade being greater than or equal to 80°.
each conductive element is made from a conductive material.

The present description also describes a flexible organic electronic device comprising a flexible module comprising an electrode, a conductive strip deposited on the electrode, an encapsulating barrier film encapsulating the module, the encapsulating barrier film including an incision defining an incision surface, the incision surface having a maximum dimension and a minimum dimension, an electrical wire, a contact member including at least one conductive element comprising a contact face, the contact face defining a contact surface, the contact surface having a maximum dimension and a minimum dimension, the maximum dimension of the incision surface being strictly smaller than the maximum dimension of the contact surface, the conductive element being assembled to the conductive strip through the incision to ensure an electronic conduction between the conductive element and the electrode.

According to one particular embodiment, the device is a photovoltaic device.

### BRIEF DESCRIPTION OF THE DRAWINGS

Other features and advantages of the invention will appear upon reading the following description of embodiments of the invention, provided as an example only and in reference to the drawings, which are:

FIG. 1, a sectional view of an organic photovoltaic module,

FIG. 2, a diagram of an example organic photovoltaic device,

FIG. 3, a diagram of part of the organic photovoltaic device of FIG. 2, the part making it possible in particular to define an incision surface and a contact surface,

FIG. 4, a diagram illustrating the incision surface relative to the contact surface according to a first example,

FIG. 5, a diagram illustrating the incision surface relative to the contact surface according to a second example, and

FIG. 6, a diagram illustrating the incision surface relative to the contact surface according to a third example.

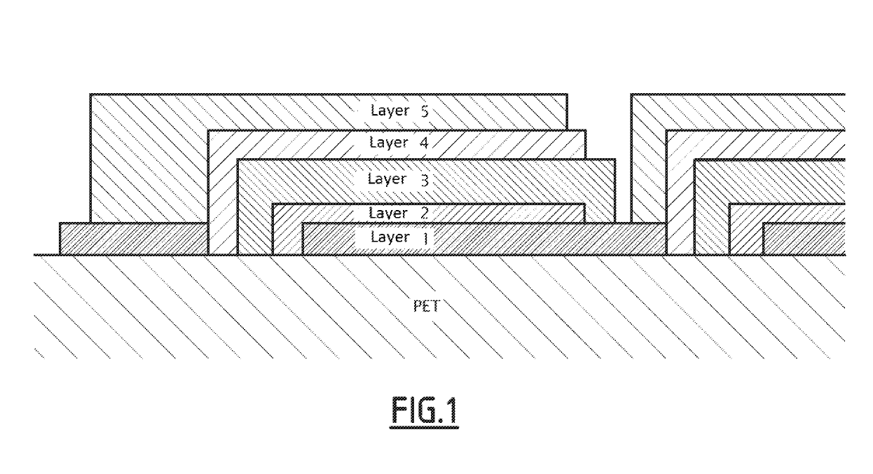

### DETAILED DESCRIPTION OF THE PREFERRED EMBODIMENTS

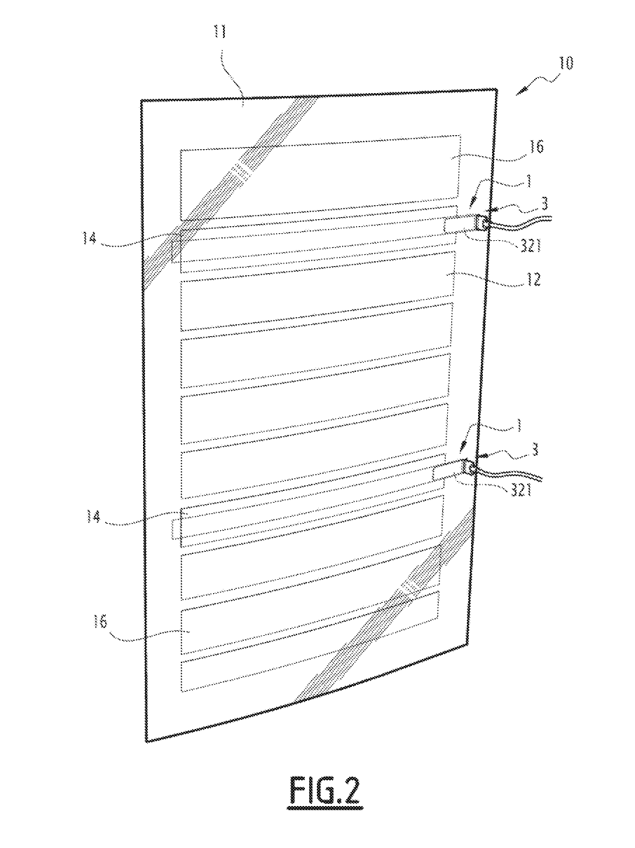

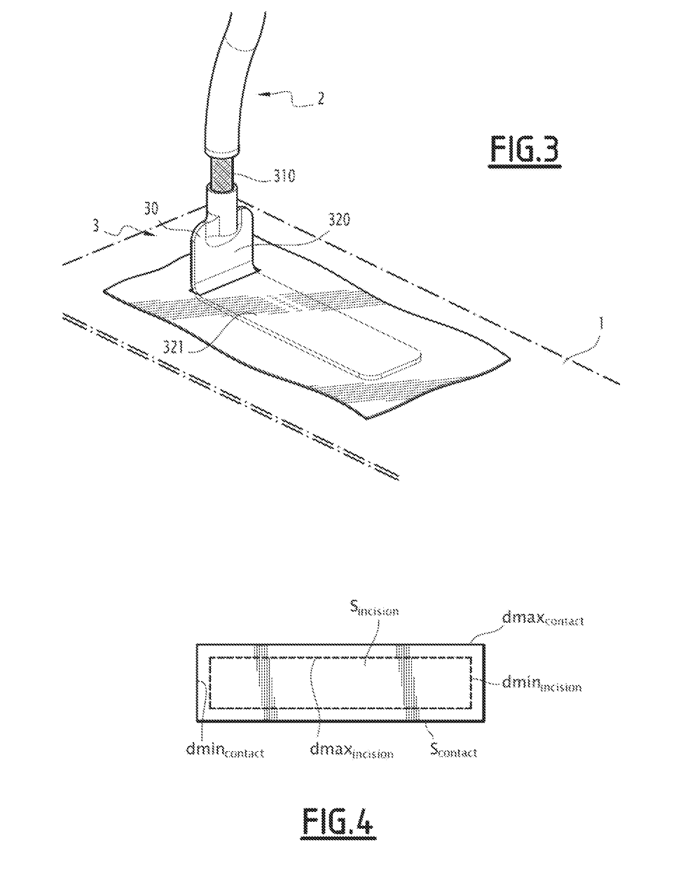

A photovoltaic device of the organic type is shown in FIG. 2, part of the photovoltaic device being detailed in FIG. 3.

A photovoltaic device is a device able to convert solar energy into electrical energy.

A photovoltaic device is qualified as organic when the active material of the photovoltaic device is organic. A material is considered to be organic when the semiconductor comprises at least one bond that is part of the group made up of covalent bonds between a carbon atom and a hydrogen atom, the covalent bonds between a carbon atom and a nitrogen atom, or bonds between a carbon atom and an oxygen atom.

The photovoltaic device is a flexible electronic device.

The photovoltaic device 10 shown in FIG. 2 assumes the form of a sheet 11 including several aligned strips 12, 14, 16. It does not appear necessary to provide a more precise description of FIG. 2, the invention being more specifically illustrated by FIG. 3, outlined below.

The photovoltaic device includes a flexible module, a conductive strip 1, an encapsulating barrier film, an electrical wire 2 and a contact member 3.

The flexible module includes an electrode.

The conductive strip 1 is deposited on the electrode.

The encapsulating barrier film encapsulates the module.

The barrier film is most often glued with self-adhesive glues (PSA type) or by UV rays.

Alternatively, the encapsulating film has no glue.

The encapsulating barrier film includes an incision.

The incision defines an incision surface S_{incision}.

The incision surface S_{incision} has a maximum dimension dmax_{incision} and a minimum dimension dmin_{incision}.

The electrical wire 2 is intended to conduct electricity.

The contact member 3 includes at least one conductive element 30.

According to the example of FIG. 2, the contact element 321 has a parallelepiped shape.

The conductive element 30 is assembled to the conductive strip 1 through the incision to ensure electronic conduction between the conductive element 30 and the electrode.

Preferably, each conductive element 30 is made from a conductive material.

The conductive element 30 comprises a contact face 321.

The contact face 321 defines a contact surface S_{contact}.

In the case at hand, the shape of the contact surface S_{contact} is rectangular.

The contact surface S_{contact} has a maximum dimension dmax_{contact} and a minimum dimension dmin_{contact}.

In the illustrated case, the maximum dimension dmax_{contact} corresponds to the length of the contact surface S_{contact} and the minimum dimension dmin_{contact} corresponds to the width of the contact surface S_{contact}.

The maximum dimension dmax_{incision} of the incision surface S_{incision} is strictly smaller than the maximum dimension dmax_{contact} of the contact surface S_{contact}.

Such a photovoltaic device is obtained by implementing a method for connecting a flexible electronic device to an electrical wire, this method being described below.

The method comprises a first step for providing a flexible electronic device.

The device includes the flexible module, the conductive strip and the encapsulating barrier film.

The method next includes a second step for providing the electrical wire 2.

The method then includes a third step for providing the contact member 3.

The method next includes an incision step of the encapsulating barrier film, the incision defining an incision surface S_{incision}

The incision step is carried out such that the maximum dimension dmaxₒₙ of the incision surface S_{incision} is strictly smaller than the maximum dimension dmax_{contact} of the contact surface S_{contact}.

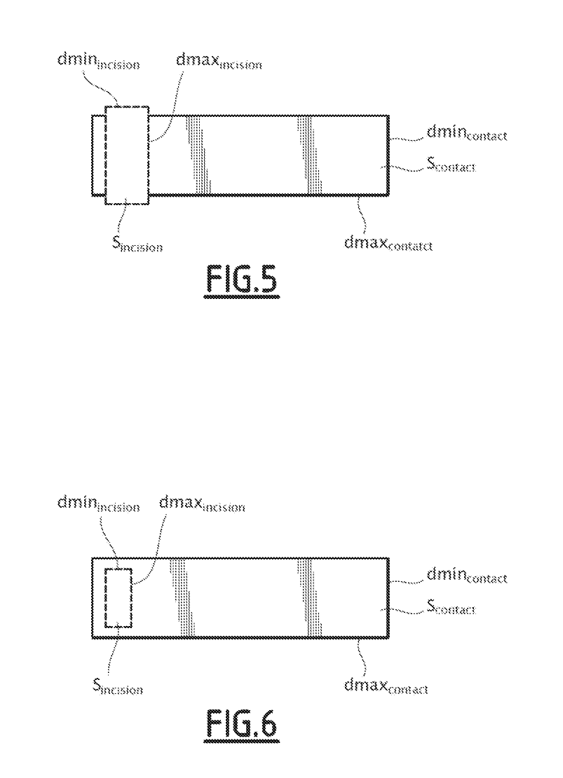

FIGS. 4 to 6 show different embodiments to carry out the incision step. The different possible embodiments are shown diagrammatically in top view below. The rectangle in solid lines shows the contact surface, while the dotted line shows the incision surface.

According to a first embodiment, the ratio between the minimum dimension dmin_{incision} of the incision surface S_{incision} and the minimum dimension dmin_{contact} of the contact surface S_{contact} is strictly less than 1.0.

More specifically, the incision surface S_{incision} is strictly included in the contact surface S_{contact}.

In this embodiment, two sides of the incision are lifted to insert the contact member 30.

According to a second embodiment, the ratio between the minimum dimension dmin_{incision} of the incision surface S_{incision} and the maximum dimension dmax_{contact} of the contact surface S_{contact} is strictly less than 0.25.

Furthermore, according to the second embodiment, the ratio between the maximum dimension dmax_{incision} of the incision surface S_{incision} and the minimum dimension dmin_{contact} of the contact surface S_{contact} is comprised between 0.9 and 1.2.

In this embodiment, the contact member 30 is inserted in the incision.

According to a third embodiment, the ratio between the minimum dimension dmin_{incision} of the incision surface S_{incision} and the maximum dimension dmax_{contact} of the contact surface S_{contact} is strictly less than 0.25.

Furthermore, the ratio between the minimum dimension dmin of the incision surface S_{incision} and the minimum dimension dmin_{contact} of the contact surface S_{contact} is strictly less than 1.0.

Moreover, the ratio between the maximum dimension dmax of the incision surface S_{incision} and the minimum dimension dmin_{contact} of the contact surface S_{contact} is strictly less than 1.0.

In this embodiment, the contact member 30 is inserted in the incision.

The method also includes a step for assembling the conductive element 30 and the conductive strip 1 through the incision to ensure electronic conduction between the conductive element 30 and the electrode.

According to one embodiment, the method includes a step for coating at least part of the contact face 321 of a metal element solidifying under heat to perform welding.

In such an embodiment, the assembly step is carried out by heating the contact face 321.

The obtained device has a better performance due to the quality of the obtained assembly.

Indeed, the proposed method minimizes the exposure of the active layers to the intrusion of air and moisture.

Furthermore, the method simplifies the steps of regaining contact with a wired connection and allowing the automation of these steps.

Additionally, the method ensures high contact reliability.

Moreover, the method contributes to the stability of the light energy conversion performance.

The method also improves the lifetime of the modules.

The method also makes it possible to have light and compact connector technology preserving the characteristics of lightness and mechanical flexibility of the modules.

To improve these effects, it is also proposed that the conductive element 30 includes an insertion blade 320 supporting the contact face 321, the insertion blade having a thickness eᵢₙₛₑᵣₜᵢₒₙ, the ratio between the minimum dimension dmin_{incision} of the incision surface S_{incision} and the thickness eᵢₙₛₑᵣₜᵢₒₙ of the insertion blade 320 is comprised between 0.9 and 1.2.

Preferably, the ratio between the minimum dimension dmin_{incision} of the incision surface S_{incision} and the thickness eᵢₙₛₑᵣₜᵢₒₙ of the insertion blade 320 is strictly less than 1.0.

Moreover, the method is simplified when the conductive element 30 includes an insertion blade 320 supporting the contact face 321 and a support blade 310, the angle between the support blade 310 and the insertion blade 320 being greater than or equal to 80°.

Such a method applies by extension to any type of flexible electronic device. In particular, this method is relevant for the entire scope of application of organic electronics (for example, OLEDs or photodetectors).

What is claimed is:

1. A method for connecting a flexible organic electronic device to an electrical wire, the method comprising:
providing a flexible electronic device, the device comprising:
a flexible module comprising an electrode,
a conductive strip deposited on the electrode, and
an encapsulating barrier film encapsulating the module,
providing an electrical wire,
providing a contact including at least one conductor comprising a contact face, the contact face defining a contact surface, the contact surface having a maximum dimension and a minimum dimension,
incision of the encapsulating barrier film defining an incision surface (S_{incision}), the incision surface having a maximum dimension and a minimum dimension, the maximum dimension of the incision surface being smaller than the maximum dimension of the contact surface, and
assembling the conductor and the conductive strip through the incision to ensure an electronic conduction between the conductor and the electrode.

2. The method according to claim 1, wherein the method further comprises coating at least part of the contact face with a metal element solidifying under heat to perform welding, and the assembling is implemented by using the contact face .

3. The method according to claim 1, wherein the ratio between the maximum dimension of the incision surface and the minimum dimension of the contact surface is comprised between 0.9 and 1.2.

4. The method according to claim 3, wherein the ratio between the maximum dimension of the incision surface and the minimum dimension of the contact surface is less than 1.0.

5. The method according to claim 1, wherein the ratio between the minimum dimension of the incision surface and the minimum dimension of the contact surface is less than 1.0.

6. The method according to claim 1, wherein the ratio between the minimum dimension of the incision surface and the maximum dimension (dmax_{contact}) of the contact surface is less than 0.25.

7. The method according to claim 1, wherein the conductor includes an insertion blade supporting the contact face, the insertion blade having a thickness, the ratio between the minimum dimension of the incision surface and the thickness of the insertion blade is comprised between 0.9 and 1.2.

8. The method according to claim 7, wherein the ratio between the minimum dimension of the incision surface and the thickness of the insertion blade is less than 1.0.

9. The method according to claim 1, wherein the conductor includes an insertion blade supporting the contact face and a support blade, the angle between the support blade and the insertion blade being greater than or equal to 80°.

10. The method according to claim 1, wherein each conductor is made from a conductive material.

11. A flexible organic electronic device, comprising:
a flexible module comprising an electrode,
a conductive strip deposited on the electrode,
an encapsulating barrier film encapsulating the module, the encapsulating barrier film including an incision defining an incision surface, the incision surface having a maximum dimension and a minimum dimension,
an electrical wire,
a contact including at least one conductor comprising a contact face, the contact face defining a contact surface, the contact surface having a maximum dimension and a minimum dimension, the maximum dimension of the incision surface being smaller than the maximum dimension of the contact surface, the conductor being assembled to the conductive strip through the incision to ensure an electronic conduction between the conductor and the electrode.

12. The device according to claim 11, wherein the device is a photovoltaic device.
